(19) United States
(12) Patent Application Publication
(10) Pub. No.: US 2005/0116583 A1
(43) Pub. Date: Jun. 2, 2005

(54) Device and method for driving ultrasonic actuator

(75) Inventors: Masahiro Nishio, Tokyo (JP); Yasuaki Kasai, Tokyo (JP)

Correspondence Address: SCULLY SCOTT MURPHY & PRESSER, PC, 400 GARDEN CITY PLAZA, SUITE 300, GARDEN CITY, NY, 11530, US

(73) Assignee: OLYMPUS CORPORATION, Tokyo (JP)

(21) Appl. No.: 10/966,966

(22) Filed: Oct. 15, 2004

(30) Foreign Application Priority Data
Nov. 27, 2003 (JP) 2003-397938
Jul. 30, 2004 (JP) 2004-224501

(51) Int. Cl. H01L 41/09

(52) U.S. Cl. 310/317

(57) ABSTRACT

A method is provided to drive an ultrasonic-actuator by supplying an alternating signal to an ultrasonic transducer in which piezoelectric plates and internal electrodes are alternately stacked. A frequency at which a phase difference between a voltage and current of the alternating signal is in a predetermined state is detected from a frequency range in which an amplitude ratio between the voltage and the current of the alternating signal is more than or equal to a predetermined value, and the driving frequency is set to the detected frequency.

### CROSS-REFERENCE TO RELATED APPLICATION

This application claims benefit of Japanese Application Nos. 2003-397938 filed on Nov. 27, 2003 and 2004-224501 filed in Japan on Jul. 30, 2004, the contents of which are incorporated by this reference.

### BACKGROUND OF THE INVENTION

1. Field of the Invention

The present invention generally relates to ultrasonic-actuator drive devices and ultrasonic-actuator drive methods and, more specifically, to an ultrasonic-actuator drive device and an ultrasonic-actuator drive method for generating a driving force by supplying a drive signal having a frequency voltage to, for example, a stacked ultrasonic transducer of an ultrasonic actuator.

2. Description of the Related Art

In recent years, attention has been given to ultrasonic actuators as motors substituting electromagnetic motors.

Such an ultrasonic actuator is typically controlled and driven by an actuator drive device. The actuator drive device supplies a drive signal having a frequency voltage to the ultrasonic transducer of the ultrasonic actuator to produce ultrasonic elliptical vibration at the ultrasonic transducer, thereby performing control such that the ultrasonic transducer or a driven portion that is in contact with the ultrasonic transducer provides a driving force.

One example of known technology for a driving method for such an ultrasonic-actuator drive device is an ultrasonic-motor drive method disclosed in Japanese Unexamined Patent Application Publication No. 63-56178. FIG. 21 shows an example of the configuration of an ultrasonic-actuator drive circuit for implementing the known ultrasonic-motor drive method.

As shown in FIG. 21, a known ultrasonic-actuator drive device includes an ultrasonic-actuator drive circuit 100 and an ultrasonic actuator 101, the driving of which is controlled by the ultrasonic-actuator drive circuit 100.

The ultrasonic-actuator drive circuit 100 includes an oscillator circuit 102, a power-amplifier circuit 103, a current detection circuit 104, a phase-difference detection circuit 105, a phase-difference condition determination circuit 106, and a frequency control circuit 107. The ultrasonic actuator 101 is connected to the power-amplifier circuit 103 via the current detection circuit 104.

The oscillator circuit 102 generates an alternating signal 102a having a frequency defined by a frequency control signal 107a output from the frequency control circuit 107, which is described below, and supplies the alternating signal 102a to the power-amplifier circuit 103.

The power-amplifier circuit 103 amplifies the alternating signal 102a and supplies a resulting drive voltage signal 103a to the current detection circuit 104 and the phase-difference detection circuit 105.

The current detection circuit 104 detects current flowing when the drive voltage signal 103a is supplied to the ultrasonic actuator 101, and supplies a drive-current detection signal 104a, which indicates the result of the detection, to the phase-difference detection circuit 105.

The phase-difference detection circuit 105 detects a phase difference between the drive voltage signal 103a and the drive-current detection signal 104a and supplies a phase-difference detection signal 105a, which indicates the result of the detection, to the phase-difference condition determination circuit 106.

When the supplied phase-difference detection signal 105a reaches a predetermined value, the phase-difference condition determination circuit 106 supplies a phase-difference condition signal 106a to the frequency control circuit 107.

The frequency control circuit 107 serves as controlling means for controlling the entire ultrasonic-actuator drive circuit 100. Thus, the frequency control circuit 107 supplies a frequency control signal 107a to the oscillator circuit 102 such that the alternating signal 102a is swept from a higher frequency to a lower frequency, thereby controlling an oscillation operation of the oscillator circuit 102.

In the ultrasonic-actuator drive circuit 100 having the above-described configuration, the frequency control circuit 107 performs control so as to change the frequency control signal 107a such that the frequency of the alternating signal 102a is swept until the phase-difference condition signal 106a to be output from the phase-difference condition determination circuit 106 is output and so as to stop the sweeping when the phase-difference detection signal 105a reaches a predetermined value. That is, the frequency control circuit 107 can perform control so as to provide the drive voltage signal 103a having a frequency at which the phase difference between the drive current and the drive voltage reaches a predetermined value. Thus, the ultrasonic-actuator drive circuit 100 allows driving at a frequency that is in a certain relationship with the resonant frequency of the ultrasonic-actuator drive circuit 100.

### SUMMARY OF THE INVENTION

In brief, the present invention provides a method for driving an ultrasonic actuator by supplying an alternating signal to an ultrasonic transducer in which piezoelectric plates and internal electrodes are alternately stacked. The method includes detecting a frequency at which a phase difference between a voltage and current of the alternating signal is in a predetermined state, from a frequency range in which an amplitude ratio between the voltage and the current of the alternating signal is more than or equal to a predetermined value; and setting a driving frequency to the detected frequency.

In brief, the present invention provides a device for driving an ultrasonic actuator by supplying an alternating signal to an ultrasonic transducer in which piezoelectric plates and internal electrodes are alternately stacked. The device includes a drive circuit for generating the alternating signal, an amplitude detection circuit for detecting an amplitude ratio between a voltage and current of the alternating signal, a phase-difference detection circuit for detecting a phase difference between the voltage and the current of the alternating signal, and a control circuit for setting a frequency of the alternating signal in accordance with the amplitude ratio and the phase difference. The control circuit detects a frequency at which the phase difference is in a predetermined state from a frequency range in which the amplitude ratio is more than or equal to a predetermined value, and sets a driving frequency to the detected frequency.

### BRIEF DESCRIPTION OF THE DRAWINGS

FIG. 1 is a block diagram showing the entire configuration of an ultrasonic-actuator drive device for realizing an ultrasonic-actuator drive method according to a first embodiment of the present invention;

FIG. 2A is a front view of an ultrasonic actuator used for the ultrasonic-actuator drive device according to the first embodiment;

FIG. 2B is a side view of the ultrasonic actuator used for the ultrasonic-actuator drive device according to the first embodiment;

FIG. 3 is a front view showing a first modification of the ultrasonic actuator in the first embodiment;

FIG. 4 is an exploded perspective view of a piezoelectric layered product in which piezoelectric plates are stacked in a Y-axis direction;

FIG. 5 is an exploded perspective view of a piezoelectric layered product in which piezoelectric plates are stacked in a Z-axis direction;

FIG. 6 is an exploded perspective view of a piezoelectric layered product in which piezoelectric plates are stacked in an X-axis direction;

FIG. 7 is a front view showing a second modification of the ultrasonic actuator;

FIG. 8A is a graph showing the characteristic of velocity versus frequency of the ultrasonic-actuator driven by the ultrasonic-actuator drive method of the first embodiment;

FIG. 8B is a graph showing the characteristic of voltage-current phase difference versus frequency of the ultrasonic-actuator driven by the ultrasonic-actuator drive method of the first embodiment;

FIG. 8C is a graph showing the characteristic of drive-current amplitude versus frequency of the ultrasonic-actuator driven by the ultrasonic-actuator drive method of the first embodiment;

FIG. 8D is a graph showing the characteristic of phase-difference detection signal versus frequency of the ultrasonic-actuator driven by the ultrasonic-actuator drive method of the first embodiment;

FIG. 9A is a graph showing the characteristic of drive-current amplitude versus frequency to describe a method for detecting the lower-limit frequency of a frequency range that defines a drive frequency and to describe a method for detecting frequency-range detection method for a frequency control circuit;

FIG. 9B is a graph showing the characteristic of drive-current amplitude versus frequency to describe a method for detecting the upper-limit frequency of a frequency range;

FIG. 9C is a graph showing the characteristic of phase-difference detection signal versus frequency to describe a frequency range based on the lower-limit frequency and the upper-limit frequency;

FIG. 10A is a graph showing the characteristic of voltage-current phase difference versus frequency in the initial stage of detection to describe a method for detecting a frequency in the vicinity of a resonant frequency in accordance with a detection result from the frequency-range detection circuit shown in FIG. 1;

FIG. 10B is a graph showing the characteristic of voltage-current phase difference versus frequency in the process of detection to describe a method for detecting a frequency in the vicinity of a resonant frequency in accordance with a detection result from the frequency-range detection circuit shown in FIG. 1;

FIG. 11 is a flow chart showing an example of a resonant-frequency detection processing routine controlled by the frequency control circuit shown in FIG. 1;

FIG. 12 is a block diagram showing the entire configuration of an ultrasonic-actuator drive device for realizing an ultrasonic-actuator drive method according to a second embodiment of the present invention;

FIG. 13A is a graph showing the characteristic of drive-current amplitude versus frequency to describe a frequency range settable by an oscillator circuit and to describe a lower-limit frequency detection method performed by the frequency control circuit;

FIG. 13B is a graph showing the characteristic of drive-current amplitude versus frequency to describe a method for detecting the lower-limit frequency of a frequency range to describe a lower-limit frequency detection method performed by the frequency control circuit;

FIG. 14 is a flow chart showing an example of a lower-limit frequency detection processing routine controlled by the frequency control circuit show in FIG. 12;

FIG. 15 is a flow chart showing an operational flow of the entire frequency control circuit when the ultrasonic-actuator drive method of the present invention is executed;

FIG. 16 is a block diagram showing the entire configuration of an ultrasonic-actuator drive device for realizing an ultrasonic-actuator drive method according to a third embodiment of the present invention;

FIG. 17A is a front view of an ultrasonic actuator used for the ultrasonic-actuator drive device in the third embodiment;

FIG. 17B is a side view of the ultrasonic actuator used for the ultrasonic-actuator drive device in the third embodiment;

FIG. 18 is a side view showing a first modification of the ultrasonic actuator in the third embodiment;

FIG. 19 is a front view showing a second modification of the ultrasonic actuator in the third embodiment;

FIG. 20A s a graph sowing the characteristic of drive-current amplitude versus frequency to describe the ultrasonic-actuator drive method of the third embodiment;

FIG. 20B is a graph showing the characteristic of frequency-setting signal versus frequency to describe the ultrasonic-actuator drive method of the third embodiment;

FIG. 20C is a graph showing the characteristic of phase-difference detection signal versus frequency to describe the ultrasonic-actuator drive method of the third embodiment and to describe a frequency range in which setting is disabled;

FIG. 21 is a block diagram showing an example of the configuration of a known ultrasonic-actuator drive circuit;

FIG. 22A illustrates the characteristic of displacement versus frequency for a longitudinal primary vibration mode of the ultrasonic transducer in the present invention;

FIG. 22B illustrates the characteristic of displacement versus frequency for a flexural secondary vibration mode of the ultrasonic transducer in the present invention; and

FIG. 23 is a graph illustrating the characteristic of velocity versus frequency of the ultrasonic transducer in the present invention.

### DESCRIPTION OF THE PREFERRED EMBODIMENTS

Embodiments of the present invention will be described below with reference to the accompanying drawings.

### First Embodiment

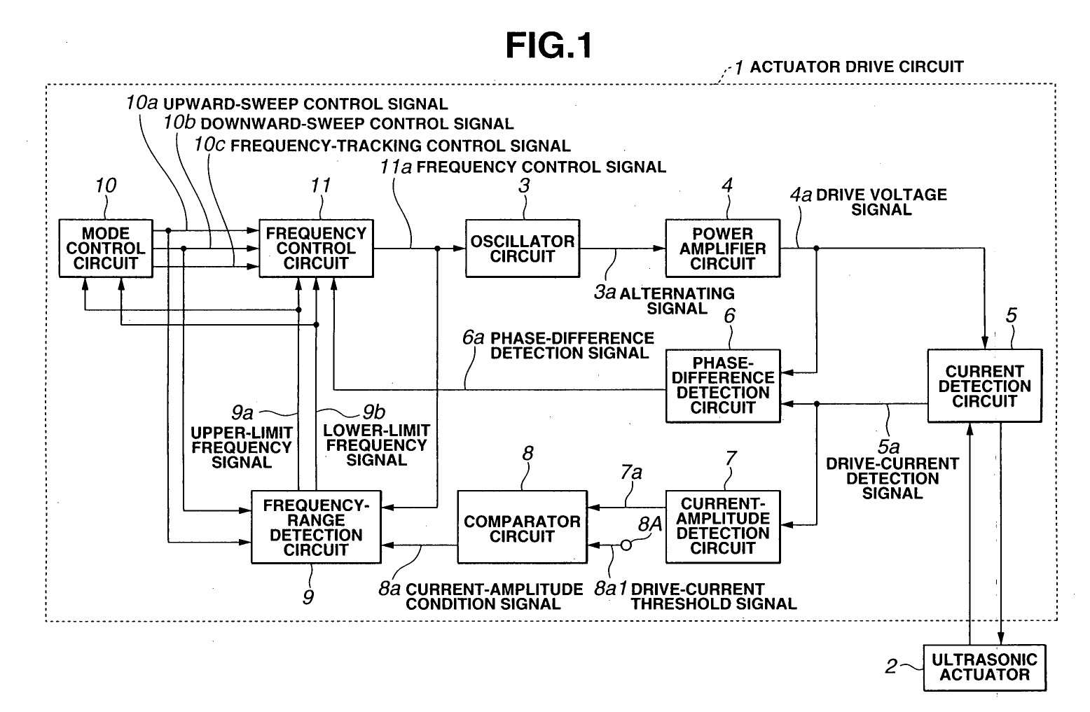

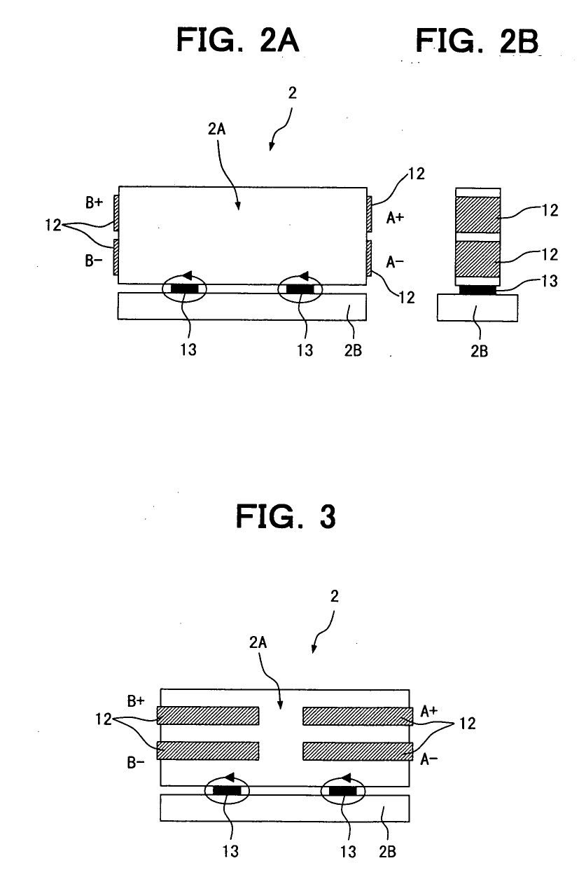

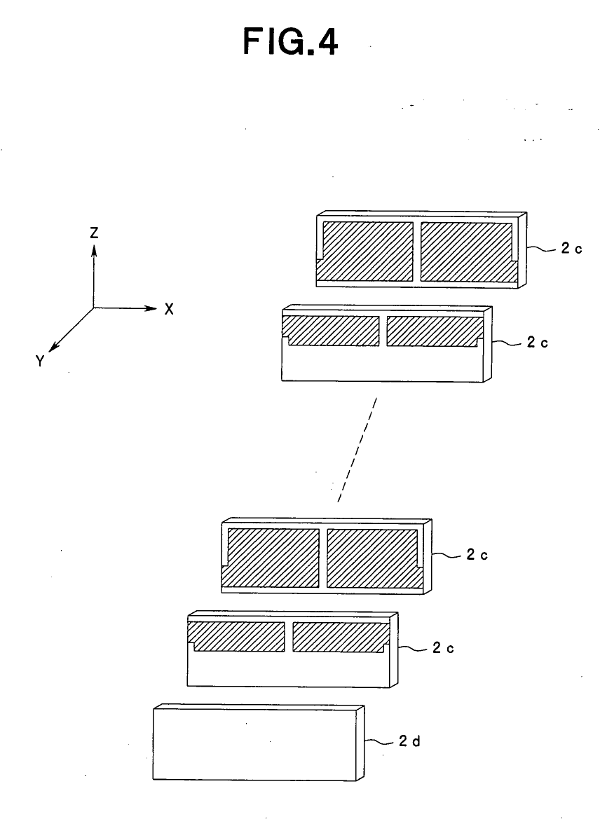

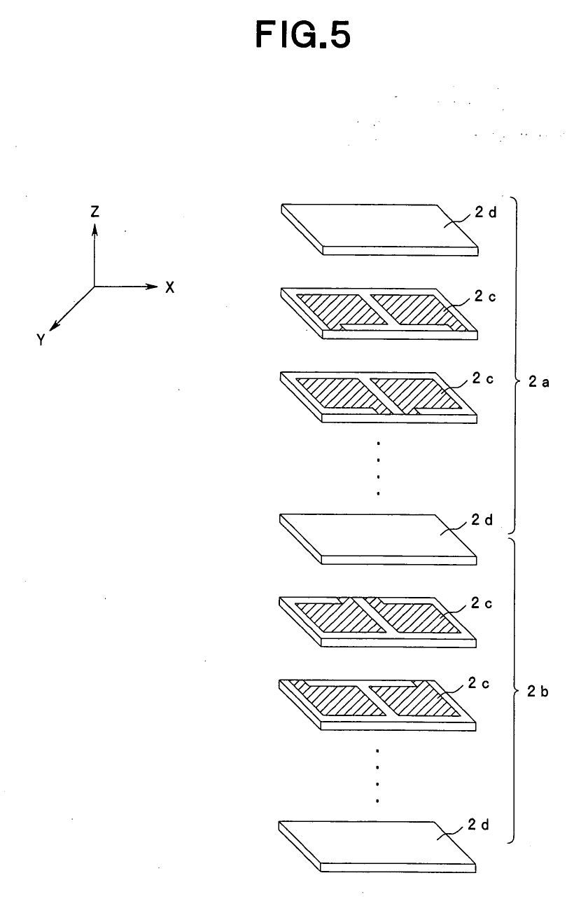

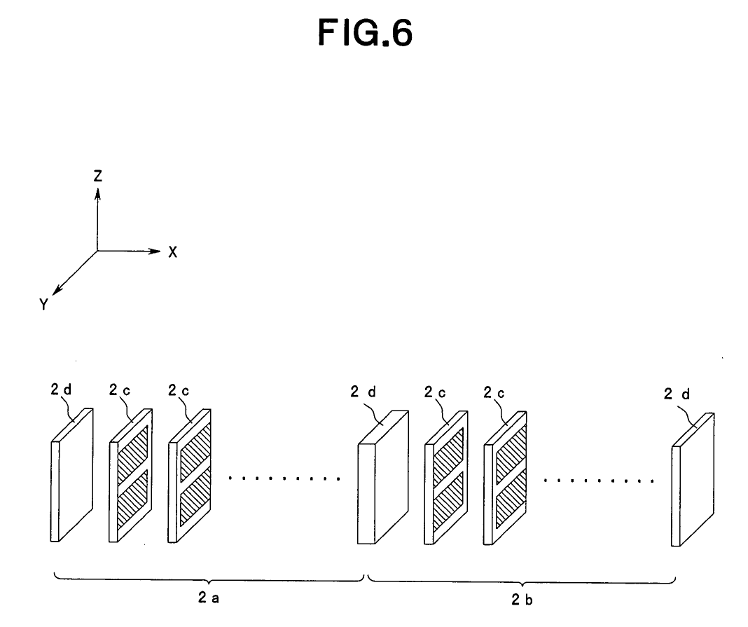

FIGS. 1 to 11 show a first embodiment of an ultrasonic-actuator drive method according to the present invention. FIG. 1 is a block diagram showing the entire structure of an ultrasonic-actuator drive device for realizing the ultrasonic-actuator drive method. FIGS. 2A and 2B show an example of the structure of an ultrasonic actuator used for the ultrasonic-actuator drive device according to this embodiment, FIG. 2A being a top view and FIG. 2B being a side view thereof. FIG. 3 is a front view showing a first modification of the ultrasonic actuator. FIGS. 4 to 6 show examples of a piezoelectric layered product of the ultrasonic actuator. Specifically, FIG. 4 is an exploded perspective view of a piezoelectric layered product in which piezoelectric plates are stacked in a Y-axis direction, FIG. 5 is an exploded perspective view of a piezoelectric layered product in which piezoelectric plates are stacked in a Z-axis direction, and FIG. 6 is an exploded perspective view of a piezoelectric layered product in which piezoelectric plates are stacked in an X-axis direction.

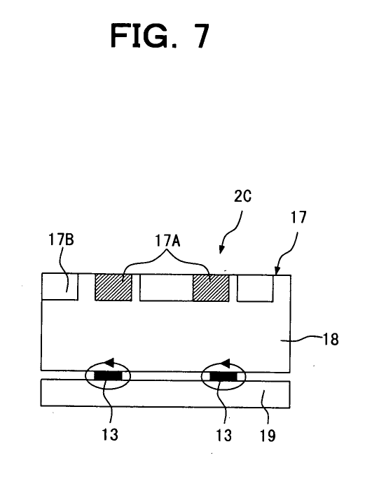

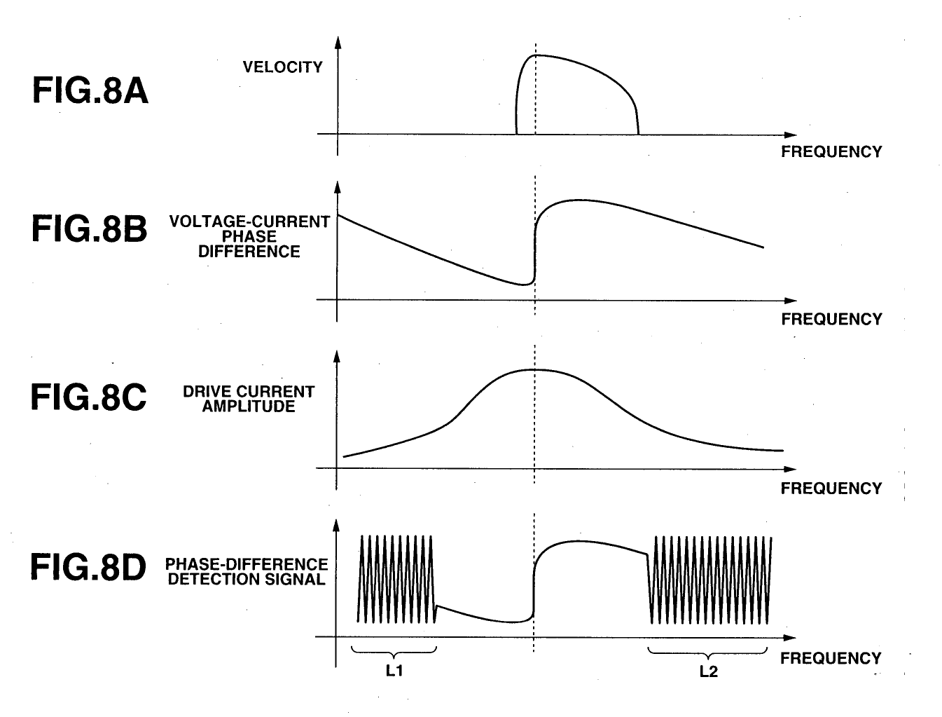

FIG. 7 is a front view showing a second modification of the ultrasonic actuator. FIGS. 8A to 8D are graphs showing characteristics of the ultrasonic-actuator driven by the ultrasonic-actuator drive method of this embodiment. Specifically, FIG. 8A is a graph showing the characteristic of velocity versus frequency, FIG. 8B is a graph showing the characteristic of voltage-current phase difference versus frequency, FIG. 8C is a graph showing the characteristic of drive-current amplitude versus frequency, and FIG. 8D is a graph showing the characteristic of phase-difference detection signal versus frequency.

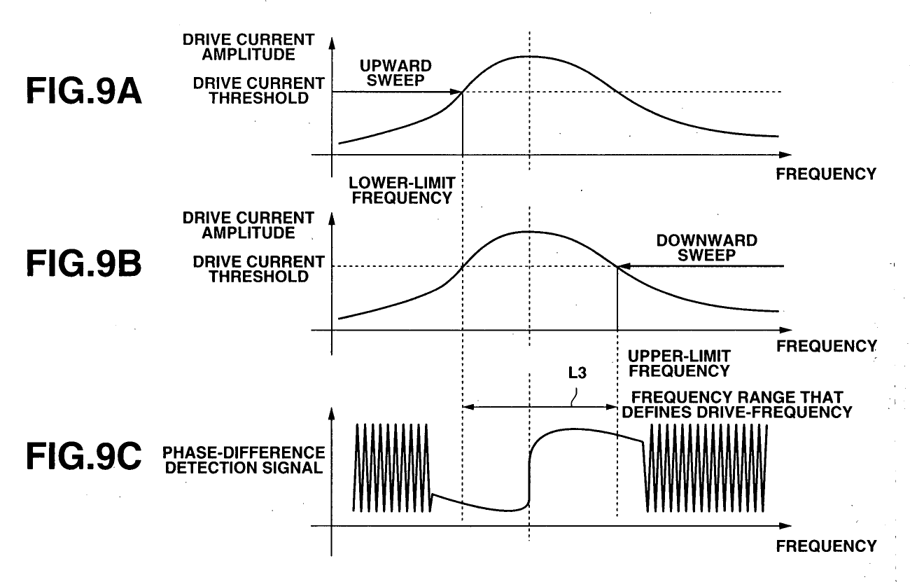

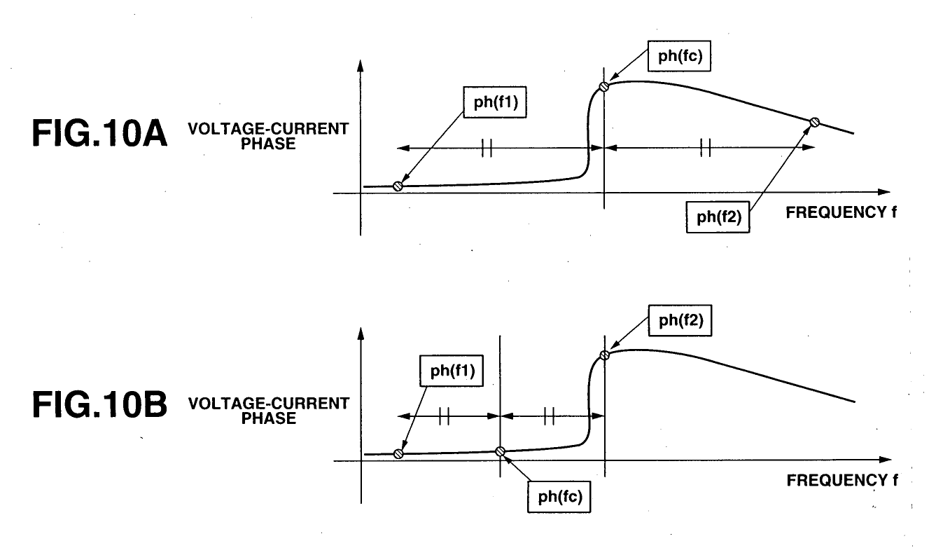

FIGS. 9A to 11 illustrate the ultrasonic-actuator drive method of this embodiment. Specifically, FIGS. 9A to 9C are graphs for describing a method for detecting a frequency range that defines a drive frequency for a frequency control circuit. FIG. 9A is a graph showing the characteristic of drive-current amplitude versus frequency to describe a method for detecting the lower-limit frequency of a frequency range. FIG. 9B is a graph showing the characteristic of drive-current amplitude versus frequency to describe a method for detecting the upper-limit frequency of a frequency range. FIG. 9C is a graph showing the characteristic of phase-difference detection signal versus frequency to describe a frequency range based on the lower-limit frequency and the upper-limit frequency.

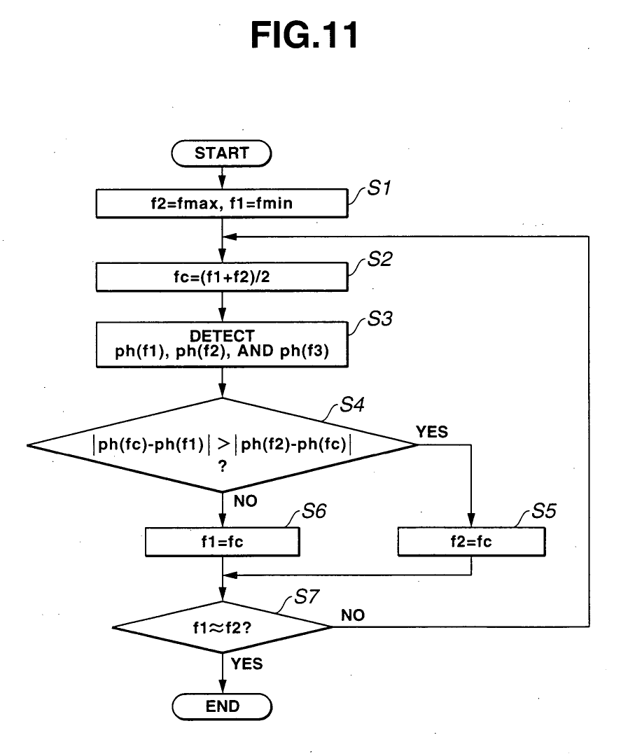

FIGS. 10A and 10B are graphs for illustrating a method for detecting a frequency in the vicinity of a resonant frequency in accordance with a detection result from a frequency-range detection circuit. FIG. 10A is a graph showing the characteristic of voltage-current phase-difference versus frequency and FIG. 10B is a graph showing the characteristic of voltage-current phase difference versus frequency. FIG. 11 is a flow chart showing an example of a resonant-frequency detection processing routine controlled by the frequency control circuit;

As shown in FIG. 1, an ultrasonic-actuator drive device of this embodiment includes an ultrasonic-actuator drive circuit 1 and an ultrasonic actuator 2, the driving of which is controlled by the ultrasonic-actuator drive circuit 1.

The ultrasonic-actuator drive circuit 1 serves as a circuit for driving the ultrasonic actuator 2, and includes an oscillator circuit 3, a power-amplifier circuit 4, a current detection circuit 5, a phase-difference detection circuit 6, a current-amplitude detection circuit 7, a comparator circuit 8, a frequency-range detection circuit 9, a mode control circuit 10, and a frequency control circuit 11. The ultrasonic actuator 2 is connected to the power-amplifier circuit 4 via the current detection circuit 5.

The structure of the ultrasonic actuator 2 will now be described.

The ultrasonic-actuator drive device of this embodiment includes, for example, the ultrasonic actuator 2 shown in FIG. 2A. As shown in FIGS. 2A and 2B, the ultrasonic actuator 2 includes an ultrasonic transducer 2A, a driven portion 2B, external electrodes 12, and friction members 13. The ultrasonic transducer 2A has a piezoelectric layered product having a rectangular prism shape. The driven portion 2B is disposed so as to be in contact with the piezoelectric layered product of the ultrasonic transducer 2A with the friction members 13 therebetween. The external electrodes 12 are provided on two opposite side surfaces of the piezoelectric layered product of the ultrasonic transducer 2A, with two external electrodes 12 on each one of the side surfaces. The friction members 13 are bonded to, for example, two spots of the bottom surface of the piezoelectric layered product of the ultrasonic transducer 2A. Predetermined pressuring means (not shown) applies pressure to the ultrasonic transducer 2A.

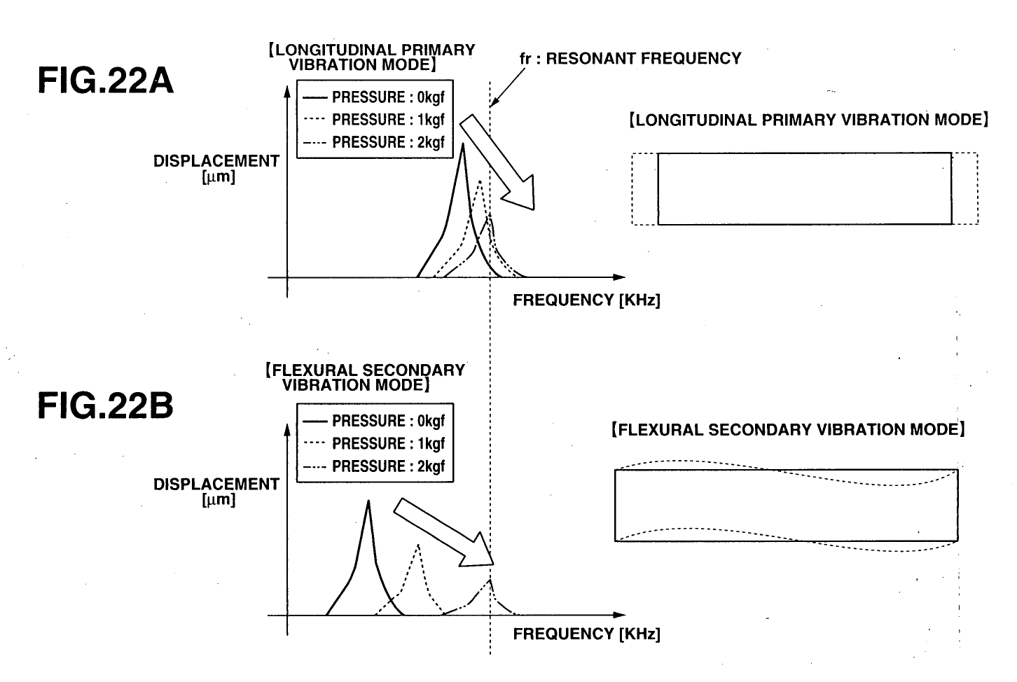

With this ultrasonic transducer 2A, when pressure applied to the ultrasonic transducer 2A varies, a displacement-to-frequency characteristic of the ultrasonic transducer 2A also varies. That is, as shown in FIGS. 22A and 22B, as the pressure increases in the order of 0 kgf, 1 kgf, and 2 kgf, the overall displacement decreases and the displacement-to-frequency characteristic shifts toward higher frequencies. The displacement-frequency characteristics between a longitudinal primary vibration mode and a flexural secondary vibration mode are different from each other in the degree of the shifting toward higher frequencies. In this embodiment, the aspect ratio (i.e., the length-to-width ratio) of the rectangular-prism piezoelectric layered product is set to a predetermined value so that the resonant frequency of the longitudinal primary vibration mode and the resonant frequency of the flexural secondary vibration mode match each other under a predetermined pressure.

As shown in FIG. 4, the piezoelectric layered product of the ultrasonic transducer 2A is integrally formed by stacking thin rectangular piezoelectric plates 2c, which have been subjected to internal-electrode processing, in a Y-axis direction (i.e., the depth direction of the ultrasonic transducer 2A, the depth direction being perpendicular to the vibration direction of the ultrasonic transducer 2A).

The external electrodes 12 located at the right hand side in FIG. 2A are attached to internal-electrode exposing portions (not shown) extracted from the right side surface of the piezoelectric layered product of the ultrasonic transducer 2A to thereby provide two electrical terminals (terminals A+ and A−), i.e., terminals A (phase A). The external electrodes 12 located at the left hand side in FIG. 2A are attached to internal-electrode exposing portions (not shown) extracted from the left side surface of the piezoelectric layered product of the ultrasonic transducer 2A to thereby provide two electrical terminals (terminals B+ and B−), i.e., terminals B (phase B). In this case, the terminals A− and B− are configured to serve as ground for the phases A and B, respectively, and thus may be configured to be at the same electrical potential using a lead line or the like.

Lead lines, which are not shown, are connected to the corresponding external electrodes 12 by soldering or the like, and are also connected to the current detection circuit 5.

The friction members 13 are provided at respective positions that correspond to belly portions of flexural vibration generated at the bottom surface of the piezoelectric layered product, so as to be in contact with the driven portion 2B.

In this exemplary structure, it is desirable that the ultrasonic transducer 2A has, for example, a longitudinal dimension of 5 to 20 mm. It is also desirable that pressure applied when the ultrasonic actuator 2, including the ultrasonic transducer 2A and the driven portion 2B, is constructed is, for example, 0.1 to 3 kgf.

The above-described exemplary structure can provide an ultrasonic actuator 2 that is preferably driven in an effective manner. The use of the ultrasonic transducer 2A having the above-described structure makes it possible to reduce component count and also to reduce variations in individual products. Further, when the drive device is designed such that the Q-value of the ultrasonic transducer 2A is constant, the resonant frequency of the longitudinal primary vibration mode and the resonant frequency of the flexural secondary vibration mode match each other under a predetermine pressure. This makes it possible to effectively execute the resonant-frequency detection processing routine described above.

In this exemplary structure, although the external electrodes 12 of the ultrasonic transducer 2A are arranged on two opposite side surfaces in the longitudinal direction of the piezoelectric layered product so as to define outer surfaces of the piezoelectric layered product, the present invention is not limited thereto. As in a first modification shown in FIG. 3, the external electrodes 12 may be extracted from side surfaces so as to be formed at surfaces of the piezoelectric layered product. Alternatively, the external electrodes 12 may be arranged at positions corresponding to reverse surfaces of the piezoelectric layered product.

Although the piezoelectric layered product of the ultrasonic transducer 2A has been described in this embodiment as having its stacking direction in the Y-axis direction, the present invention is not limited thereto. For example, as shown in FIG. 5, a first piezoelectric layered product 2a, which is a substantially-upper-half portion of the piezoelectric layered product of the ultrasonic transducer 2A, and a second piezoelectric layered product 2b, which is a substantially-lower-half portion of the piezoelectric layered product of the ultrasonic transducer 2A, may be stacked in the Z-axis direction (i.e., the vertical direction, which is perpendicular to the driving direction of the ultrasonic transducer 2A) with an insulating piezoelectric sheet 2d interposed therebetween. Further, as shown in FIG. 6, a first piezoelectric layered product 2a, which is a substantially-left-half portion of the piezoelectric layered product of the ultrasonic transducer 2A, and a second piezoelectric layered product 2b, which is a substantially-right-half portion of the piezoelectric layered product of the ultrasonic transducer 2A, may be stacked in the X-axis direction (i.e., the horizontal direction, which is parallel to the driving direction of the ultrasonic transducer 2A) with an insulating piezoelectric sheet 2d interposed therebetween.

In addition, although the ultrasonic actuators 2 of the first embodiment and the first modification have been described as having a structure in which the piezoelectric structure is integrally constructed with the insulating layer (not shown) interposed therebetween, the present invention is not limited thereto. For example, the ultrasonic actuator 2 may be configured as an ultrasonic actuator 2C of a second modification shown in FIG. 7. The ultrasonic transducer of the ultrasonic actuator 2C has a base elastic body 18 having a rectangular prism shape, at least two stacked piezoelectric elements 17A, holding elastic bodies 17B, friction members 13, and a contact portion 19 that serves as a driven portion. The stacked piezoelectric elements 17A are secured to the base elastic body 18 so as to be parallel to each other in the longitudinal direction thereof. The holding elastic bodies 17B press and sandwich the stacked piezoelectric elements 17A with respect to the base elastic body 18. The friction members 13 are provided at positions corresponding to belly portions of flexural vibration generated at a surface of the base elastic body 18, so as to be in contact with the contact portion 19.

FIGS. 8A to 8D show characteristics of the above-described ultrasonic actuator 2. In a velocity-frequency characteristic shown in FIG. 8A, when the ultrasonic actuator 2 is driven at a frequency f in a frequency range lower than a resonant frequency (a portion indicated by a dotted line shown in FIG. 8A), the velocity decreases sharply. Conversely, when the ultrasonic actuator 2 is driven at a frequency f in a frequency range higher than the resonant frequency, the velocity decreases gradually and decreases sharply at a certain point.

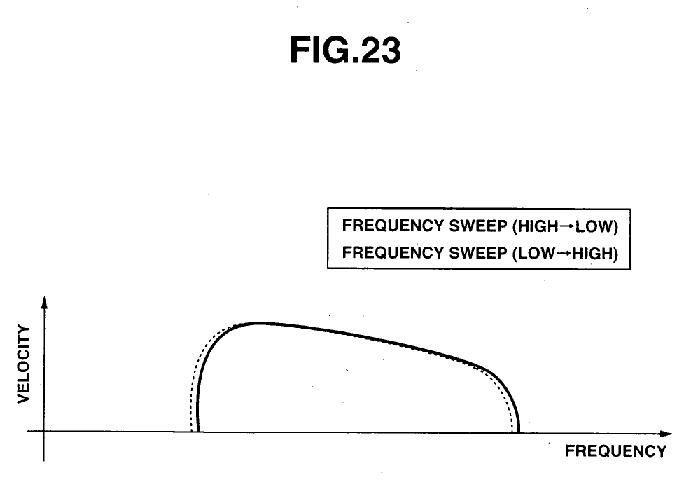

In the ultrasonic actuator 2, the velocity-frequency characteristic is hardly changed depending on the sweep direction of the frequency and almost no hysteresis phenomenon occurs. Thus, as shown in FIG. 23, the ultrasonic actuator 2 exhibits almost no difference between the velocity-frequency characteristic obtained by sweeping the frequency from the higher side of the resonant frequency toward the lower side and the velocity-frequency characteristic obtained by sweeping the frequency from the lower side of the resonant frequency toward the higher side.

In conjunction with the velocity-frequency characteristic, the ultrasonic actuator 2 has the characteristic of voltage-current phase-difference versus frequency, as shown in FIG. 8B. That is, the characteristic of voltage-current phase difference versus frequency displays a significant change in the phase difference in the vicinity of the resonant frequency, and also does not depend on the sweep direction of the frequency. Further, with the ultrasonic actuator 2, in the drive-current amplitude versus frequency characteristic shown in FIG. 8C, current that is sufficient for detecting a phase difference flows in the vicinity of the resonant frequency. However, the current amplitude decreases when the frequency is away from the resonant frequency, thereby making it difficult to accurately detect the phase difference, as shown in FIG. 8D.

Accordingly, with respect to the ultrasonic transducer 2A of the ultrasonic actuator 2 having the above-described characteristics, the ultrasonic-actuator drive circuit 1 in the ultrasonic-actuator drive device of this embodiment can drive the ultrasonic actuator 2 with high drive efficiency, by accurately performing phase detection and reliably supplying an alternating signal having a frequency in the vicinity of the resonant frequency.

Next, the configuration of the ultrasonic-actuator drive circuit 1 of this embodiment will be described with reference to FIG. 1.

As shown in FIG. 1, the oscillator circuit 3 included in the ultrasonic-actuator drive circuit 1 generates an alternating signal 3a having a frequency defined by a frequency control signal 11a output from the frequency control circuit 11, and supplies the generated alternating signal 3a to the power-amplifier circuit 4.

The power-amplifier circuit 4 amplifies the alternating signal 3a and outputs and supplies an amplified drive voltage signal 4a to the ultrasonic actuator 2 via the current detection circuit 5. In accordance with the supplied drive voltage signal 4a, the ultrasonic actuator 2 is driven.

The current detection circuit 5 detects current flowing when the drive voltage signal 4a is supplied to the ultrasonic actuator 2, and outputs and supplies a drive-current detection signal 5a, which indicates the detection current, to the phase-difference detection circuit 6 and the current-amplitude detection circuit 7.

The phase-difference detection circuit 6 detects a phase difference between the drive voltage signal 4a and the drive-current detection signal 5a and outputs and supplies a phase-difference detection signal 6a to the frequency control circuit 11.

The current-amplitude detection circuit 7 detects the amplitude of the drive-current detection signal 5a and supplies an amplitude result signal 7a, which indicates the detected amplitude, to one input end of the comparator circuit 8. A drive-current threshold signal 8a1, which serves as a reference for comparison processing, is supplied to the other input end of the comparator circuit 8 from drive-current threshold-signal generating means (not shown) connected to an input terminal 8A.

The comparator circuit 8 outputs and supplies a current-amplitude condition signal 8a to the frequency-range detection circuit 9, when the amplitude result signal 7a from the current-amplitude detection circuit 7 exceeds the drive-current threshold signal 8a1 having a predetermined value.

While an upward-sweep control signal 10a output from the mode control circuit 10 described below is input, the frequency-range detection circuit 9 outputs, as a lower-limit frequency signal 9b, a frequency control signal at a point when the input of the current-amplitude condition signal 8a is started. While a downward-sweep control signal 10b output from the mode control circuit 10 is input, the frequency-range detection circuit 9 outputs, as an upper-limit frequency signal 9a, a frequency control signal at a point when the input of the current-amplitude condition signal 8a is started. The frequency-range detection circuit 9 supplies the upper-limit frequency signal 9a and the lower-limit frequency signal 9b to the mode control circuit 10 and the frequency control circuit 11.

The mode control circuit 10 and the frequency control circuit 11 serve as controlling means (i.e., a control circuit) for controlling the entire ultrasonic-actuator drive circuit 1 of this embodiment).

The mode control circuit 10 outputs the upward-sweep control signal 10a before the driving of the ultrasonic actuator 2 is started. After the lower-limit frequency signal 9b is output from the frequency-range detection circuit 9, the mode control circuit 10 stops the output of the upward-sweep control signal 10a and outputs the downward-sweep control signal 10b. After the upper-limit frequency signal 9a is output from the frequency-range detection circuit 9, the mode control circuit 10 stops the output of the downward-sweep control signal 10b and outputs a frequency-tracking control signal 10c. The mode control circuit 10 supplies the upward-sweep control signal 10a, the downward-sweep control signal 10b, and the frequency-tracking control signal 10c to the frequency control circuit 11.

While the upward-sweep control signal 10a is input, the frequency control circuit 11 changes the frequency control signal 11a such that the frequency of the alternating signal 3a varies from low to high. While the downward-sweep control signal 10b is input, the frequency control circuit 11 changes the frequency control signal 11a such that the frequency of the alternating signal 3a varies from high to low. While the frequency-tracking control signal 10c is input, the frequency control circuit 11 detects a frequency at which the amount of change in the phase-difference detection signal 6a relative to the frequency is a maximum, from a frequency range defined by the upper-limit frequency signal 9a and the lower-limit frequency signal 9b. After completing the detection of the frequency, the frequency control circuit 11 performs control such that the drive frequency is set to the detected frequency.

Although the current-amplitude detection circuit 7 is configured to detect the amplitude of the drive-current detection signal 5a, another configuration may be employed. For example, the current-amplitude detection circuit 7 may be configured to detect the ratio of the amplitude of the drive voltage signal 4a to the amplitude of the drive-current detection signal 5a or may be configured to derive the admittance of the ultrasonic actuator 2.

Although the phase-difference detection circuit 6 is configured to output a phase difference between the drive voltage signal 4a and the drive-current detection signal 5a, the phase-difference detection circuit 6 may be configured to output a phase difference between the alternating signal 3a and the drive-current detection signal 5a.

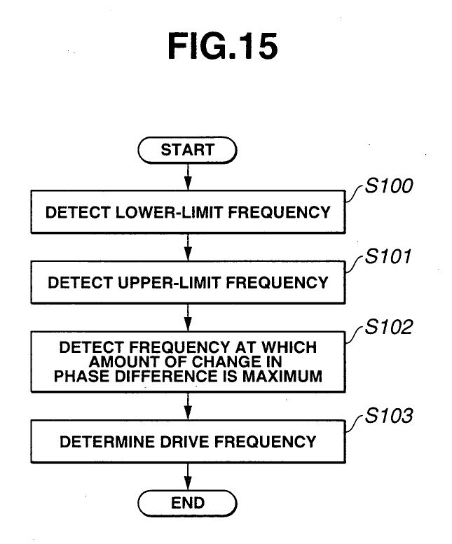

The operation of the ultrasonic-actuator drive circuit 1 of this embodiment will now be described with reference to FIGS. 9A to 9C and 15. FIG. 15 is a flow chart showing an operational flow of the entire frequency control circuit 11 when an ultrasonic-actuator drive method of the present invention is executed.

In the ultrasonic-actuator drive circuit 1 having the above-described configuration, in step S100, the frequency control circuit 11 performs control so as to sweep the frequency of the drive voltage signal 4a from low to high in the early stage of driving, as shown in FIG. 9A, and so as to detect the lower limit of a frequency range in which the drive-current amplitude (i.e., the amplitude result signal 7a) exceeds a value defined by the drive-current threshold signal 8a1.

Subsequently, in step S101, the frequency control circuit 11 performs control so as to sweep the frequency of the drive voltage signal 4a from high to low, as shown in FIG. 9B, and so as to detect the upper limit of a frequency range in which the drive-current amplitude (i.e., the amplitude result signal 7a) exceeds a value defined by the drive-current threshold signal 8a1.

It is preferable in this case that the drive-current threshold signal 8a1 is set to a value corresponding to a minimum current amplitude value that allows for accurate determination of the phase difference between the drive voltage signal 4a and the drive-current detection signal 5a.

In step S102, as shown in FIG. 9C, the frequency control circuit 11 performs control so as to detect a frequency at which the amount of change in the phase-difference detection signal 6a relative to the frequency is a maximum, from between the detected upper limit and the lower limit of a frequency range L3. After completing the detection, in step S103, the frequency control circuit 11 performs control so as to set the drive frequency to the detected frequency.

Next, a method for detecting a frequency at which the amount of change in the phase-difference detection signal 6a relative to the frequency is a maximum (i.e., a detection processing method in step S102 shown in FIG. 15) will now described with reference to FIGS. 10A, 10B, and 11.

When the driving method for the ultrasonic-actuator drive device of this embodiment is executed, the frequency control circuit 11 starts a resonant-frequency detection processing routine shown in FIG. 11, so that processing in steps S1 to S7 is executed.

In step S1, the frequency control circuit 11 substitutes the upper value fmax of a frequency range (where fmax indicates the upper limit and fmin indicates the lower limit), including the resonant frequency detected based on the voltage-current phase difference characteristic shown in FIG. 10A, into a frequency f2 and substitutes the lower-limit value fmin into a frequency f1.

In processing in step S2, the frequency control circuit 11 determines the intermediate value (f1+f2)/2 of the frequency f1 and the frequency f2 and substitutes the intermediate value (f1+f2)/2 into a frequency fc.

Subsequently, in processing step S3, the frequency control circuit 11 detects a voltage-current phase difference (hereinafter referred to as a “phase difference”) corresponding to each of the frequency f1, the frequency f2, and the frequency fc. The frequency control circuit 11 then substitutes the phase difference detected at the frequency f1, the phase difference detected at the frequency f2, and the phase difference detected at the frequency fc into ph(f1), ph(f2), and ph(fc), respectively.

Subsequently, in determination processing in step S4, the frequency control circuit 11 compares |ph(fc)−ph(f1)| with |ph(f2)−ph(fc)|. When |ph(f2)−ph(fc)| is smaller, the frequency control circuit 11 replaces the value of the frequency f2 with the value of the frequency fc in processing in step S5 and then the process proceeds to processing in step S7. When |ph(fc)−ph(f1)| is smaller, the frequency control circuit 11 replaces the value of the frequency f1 with the value of the frequency fc in processing in step S6 and then the process proceeds to processing in step S7.

FIG. 10B shows a case in which |ph(f2)−ph(fc)| is smaller. Thus, in the processing in step S5, the frequency control circuit 11 replaces the value of the frequency f2 with the value of the frequency fc.

Thereafter, in determination processing in step S7, the frequency control circuit 11 determines whether or not the frequency f1 is substantially equal to the frequency f2. In this case, when the frequency control circuit 11 determines that the relationship of f1≈f2 is not satisfied, i.e., the frequency f1 is not equal to the frequency f2, the process returns to the processing in step S2 and the processing in step S2 is repeated.

On the other hand, when the frequency control circuit 11 determines that the relationship of f1≈f2 is satisfied in the determination processing in step S7, the frequency control circuit 11 recognizes that the relationship of f1≈f2 is satisfied and also sets the value of a frequency at this point as a value in the vicinity of a resonant frequency which is preferable for driving the ultrasonic transducer 2A. The frequency control circuit 11 then ends this resonant-frequency detection processing routine.

Thus, the frequency control circuit 11 repeatedly executes the processing in step S2 to the processing in step S6 until the relationship of f1≈f2 is satisfied, which makes it possible to detect a frequency in the vicinity of the resonant frequency.

Thus, the above described operation in this embodiment can ensure that the driving frequency is set to a frequency in the vicinity of the resonant frequency while avoiding a range in which the phase difference between the drive voltage and the drive current cannot be accurately determined due to a small drive current. This arrangement, therefore, allows the ultrasonic actuator 2 to be driven with high driving efficiency.

In this embodiment, although the frequency control circuit 11 performs control so as to perform the downward sweep after performing the upward sweep, the frequency control circuit 11 may perform control so as to perform the downward sweep first and then perform the upward sweep. Such an arrangement can provide the same advantages as the above-described embodiment.

Although the description in the above-described embodiment has been given of a case in which the entire ultrasonic-actuator drive circuit 1 is constituted by circuits, the present invention is not limited thereto. For example, a microcomputer or the like can be used to constitute the ultrasonic-actuator drive circuit 1 with software. In such a case, for example, a configuration in which the frequency control circuit 11, the frequency-range detection circuit 9, and the mode control circuit 10 are replaced with software may be employed.

### Second Embodiment

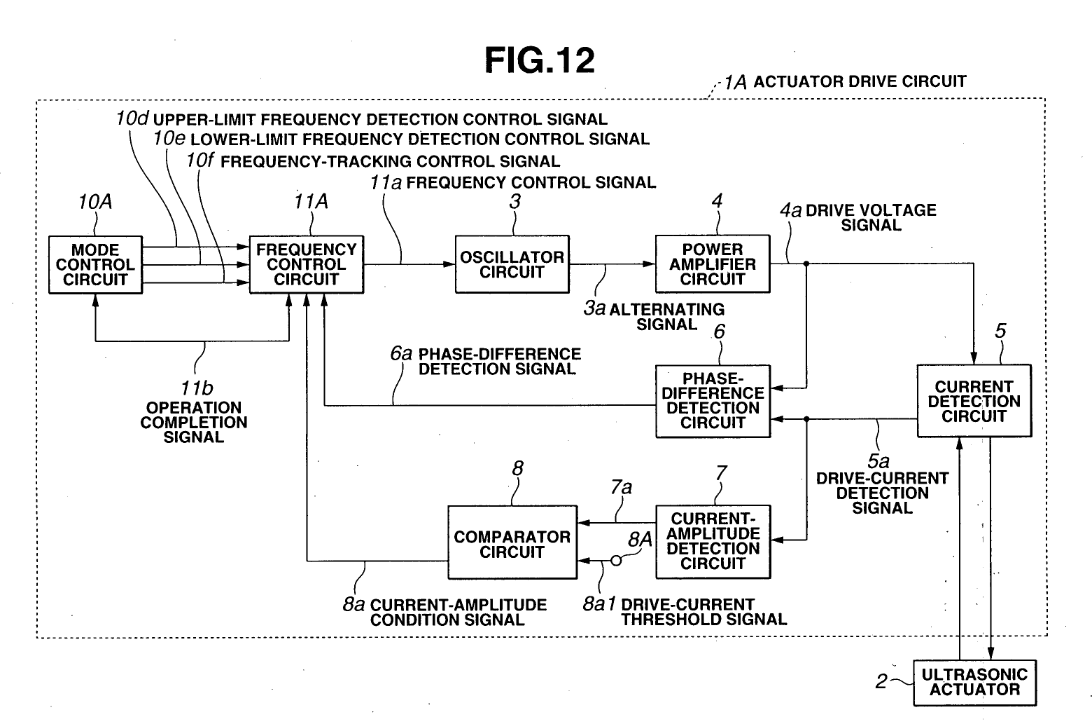

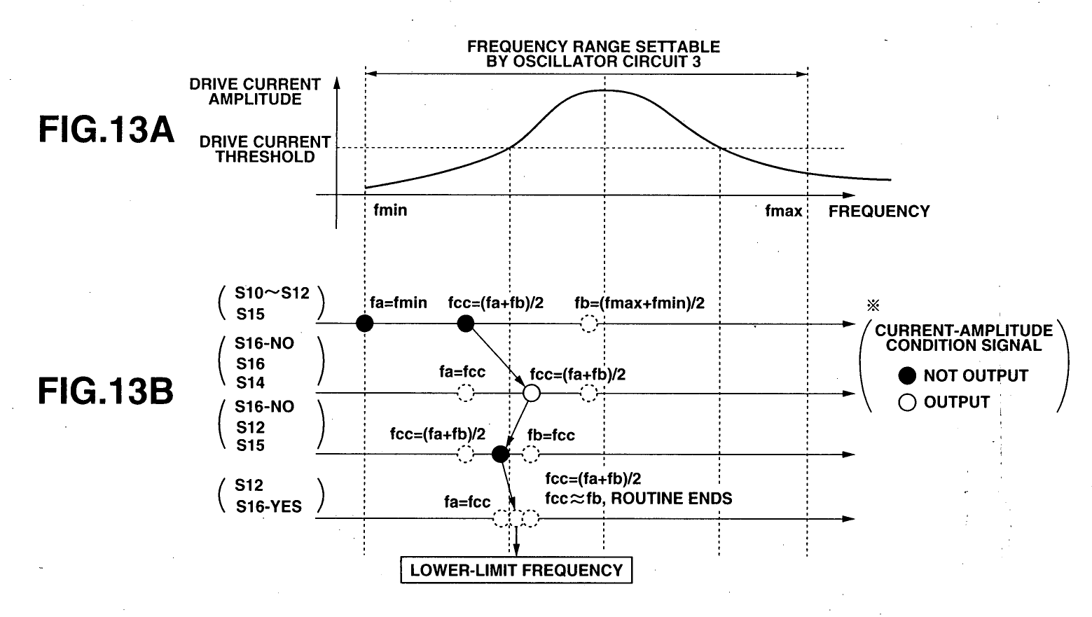

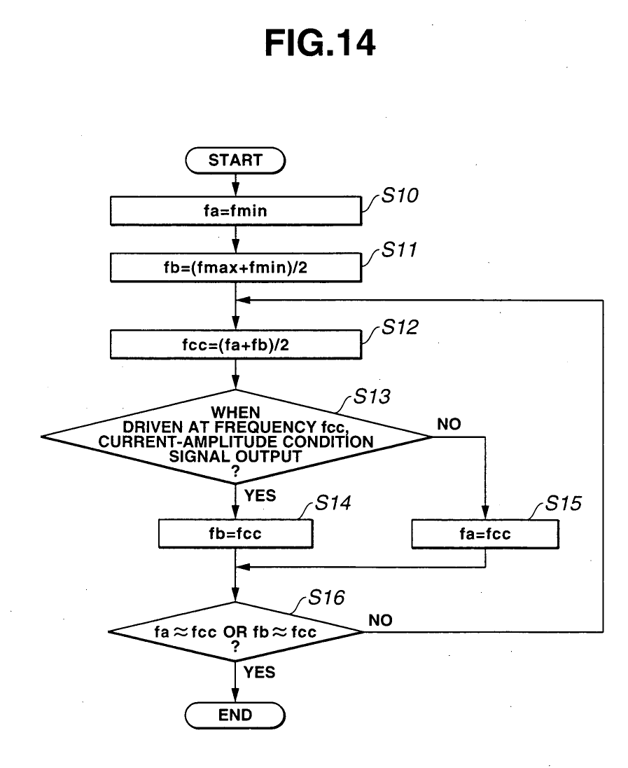

FIGS. 12 to 15 show a second embodiment of the ultrasonic-actuator drive method of the present invention. Specifically, FIG. 12 is a block diagram showing the entire configuration of an ultrasonic-actuator drive device for realizing the ultrasonic-actuator drive method. FIGS. 13A, 13B, 14, and 15 illustrate the ultrasonic-actuator drive method of the second embodiment. More specifically, FIGS. 13A and 13B are graphs for describing a lower-limit frequency detection method for a frequency control circuit. FIG. 13A is a graph showing the characteristic of drive-current amplitude versus frequency to describe a frequency range that can be set by an oscillator circuit and FIG. 13B is a graph showing the characteristic of drive-current amplitude versus frequency to describe a method for detecting the lower-limit frequency of the frequency range. FIG. 14 is a flow chart showing an example of controlling of a lower-limit frequency detection processing routine performed by a frequency control circuit. FIG. 15 is a flow chart showing an operational flow of the entire frequency control circuit when the ultrasonic-actuator drive method of the present invention is executed. FIG. 15 is also common to both the first and second embodiments. In FIG. 12, the same elements as those in the first embodiment are denoted with the same reference numerals, and thus the descriptions thereof are omitted and only different elements and portions will be described.

The ultrasonic-actuator drive device of this embodiment includes an ultrasonic-actuator drive circuit 1A and an ultrasonic actuator 2. This ultrasonic actuator 2 is analogous to that in the first embodiment. In the ultrasonic-actuator drive circuit 1A, the frequency-range detection circuit 9 in the first embodiment is eliminated.

As shown in FIG. 12, in the ultrasonic-actuator drive circuit 1A, an oscillator circuit 3 generates an alternating signal 3a having a frequency defined by a frequency control signal 11a output from a frequency control circuit 11A, and supplies the generated alternating signal 3a to a power-amplifier circuit 4.

The power-amplifier circuit 4 amplifies the alternating signal 3a and outputs and supplies a drive voltage signal 4a to the ultrasonic actuator 2 via a current detection circuit 5. In accordance with the supplied drive voltage signal 4a, the ultrasonic actuator 2 is driven.

The current detection circuit 5 detects current flowing when the drive voltage signal 4a is supplied to the ultrasonic actuator 2, and outputs and supplies a drive-current detection signal 5a, which indicates the result of the detection, to a phase-difference detection circuit 6 and a current-amplitude detection circuit 7.

The phase-difference detection circuit 6 detects a phase difference between the drive voltage signal 4a and the drive-current detection signal 5a and outputs and supplies a phase-difference detection signal 6a, which indicates the result of the detection, to the frequency control circuit 11A.

The current-amplitude detection circuit 7 detects the amplitude of the drive-current detection signal 5a and supplies an amplitude result signal 7a, which indicates the detected amplitude, to one input end of a comparator circuit 8. A drive-current threshold signal 8a1, which serves as a reference for comparison processing, is supplied to the other input end of the comparator circuit 8 from drive-current threshold-signal generating means (not shown) connected to an input terminal 8A.

The comparator circuit 8 outputs and supplies a current-amplitude condition signal 8a to the frequency control circuit 11A, when the amplitude result signal 7a supplied from the current-amplitude detection circuit 7 exceeds the drive-current threshold signal 8a1 having a predetermined value.

A mode control circuit 10A and the frequency control circuit 11A serve as controlling means for controlling the entire ultrasonic-actuator drive circuit 1A of this embodiment.

The mode control circuit 10A outputs a lower-limit frequency detection control signal 10e before the driving of the ultrasonic actuator 2 is started. After an operation completion signal 11b is supplied from the frequency control circuit 11A, the mode control circuit 10A stops the output of the lower-limit frequency detection control signal 10e and outputs an upper-limit frequency detection control signal 10d. After the operation completion signal 11b is supplied from the frequency control circuit 11A, the mode control circuit 10A stops the output of the upper-limit frequency detection control signal 10d and outputs a frequency-tracking control signal 10f. This mode control circuit 10A supplies the lower-limit frequency detection control signal 10e, the upper-limit frequency detection control signal 10d, and the frequency-tracking control signal 10f to the frequency control circuit 11A.

In a state in which the lower-limit frequency control signal 10e is input, the frequency control circuit 11A detects a lower-limit frequency at which the current-amplitude condition signal 8a is output, while changing the frequency in a discrete manner. In a state in which the upper-limit frequency detection control signal 10d is input, the frequency control circuit 11A detects an upper-limit frequency at which the current-amplitude condition signal 8a is output, while changing the frequency in a discrete manner. Further, in a state in which the frequency-tracking control signal 10f is input, the frequency control circuit 11A detects a frequency at which the amount of change in the phase-difference detection signal 6a relative to the frequency is a maximum, from a frequency range defined by the upper-limit frequency and the lower-limit frequency. After completing the frequency detection, the frequency control circuit 11A performs control so as to set the drive frequency to the detected frequency.

Other configurations are analogous to those in the first embodiment.

The operation of the ultrasonic-actuator drive circuit 1A of this embodiment will now be described with reference to FIG. 15.

In the ultrasonic-actuator drive circuit 1A having the above-described configuration, in step S100, the frequency control circuit 11A performs control in the early stage of driving so as to detect the lower-limit frequency (the lower-limit value) of a frequency range in which the drive-current amplitude (i.e., the amplitude result signal 7a) exceeds a value defined by the drive-current threshold signal 8a1.

Subsequently, in step S101, the frequency control circuit 11A performs control so as to detect the upper-limit frequency (the upper limit value) of a frequency range in which the drive-current amplitude (i.e., the amplitude result signal 7a) exceeds a value defined by the drive-current threshold signal 8a1.

It is preferable in this case that the drive-current threshold signal 8a1 is set to a value corresponding to a minimum current amplitude value that allows for accurate determination of the phase difference between the drive voltage signal 4a and the drive-current detection signal 5a.

In step S102, the frequency control circuit 11A detects a frequency at which the amount of change in the phase-difference detection signal 6a relative to the frequency is a maximum, from between the detected upper limit and lower limit of a frequency range L3 (see FIG. 9C).

Lastly, in step S103, the frequency control circuit 11A performs control so as to set the drive frequency to the frequency detected in processing in step S102.

A method for detecting the lower-limit frequency in step S100 will now be described with reference to FIGS. 13A, 13B, and 14.

When a drive method for the ultrasonic-actuator drive device in this embodiment is executed to perform the processing in step S100 shown in FIG. 15, the frequency control circuit 11A starts a lower-limit detection processing routine shown in FIG. 14 and processing of steps S10 to S16 is executed.

In step S10, the frequency control circuit 11A substitutes the lower limit fmin of a frequency range (where fmax indicates the upper limit and fmin indicates the lower limit shown in FIG. 13A) settable by the oscillator circuit 3 into a frequency fa.

Subsequently, in processing in step S11, the frequency control circuit 11A substitutes an intermediate value (fmax+fmin)/2 of the upper limit fmax and the lower limit fmin into a frequency fb (see FIG. 13B), and the process proceeds to step S12.

Thereafter, in processing in step S12, the frequency control circuit 11A substitutes an intermediate value (fa+fb)/2 of the frequency fa and the frequency fb into a frequency fcc, and the process proceeds to step S13.

Next, in determination processing in step S13, the frequency control circuit 11A determines whether or not the current-amplitude condition signal 8a is output when driven at the frequency fcc. In this case, as shown in FIG. 13B, when it is determined that the current-amplitude condition signal 8a is not output, the process proceeds to step S15, in which the frequency control circuit 11A replaces the frequency fa with the frequency fcc. The process then proceeds to determination processing in step S16. On the other hand, when it is determined in step S13 that the current-amplitude condition signal 8a is output, the process proceeds to step S14, in which the frequency control circuit 11A replaces the frequency fb with the frequency fcc. The process then proceeds to determination processing in step S16.

In the determination processing in step S16, the frequency control circuit 11A determines whether or not the frequency fa is substantially equal to the frequency fcc or the frequency fb is substantially equal to the frequency fcc. In this case, when the frequency control circuit 11A determines that they are not equal to each other, i.e., the relationship of fa≈fcc or fb≈fcc is not satisfied, the process returns to the processing in step S12 and the processing in step S12 is repeated.

On the other hand, when the frequency control circuit 11A determines that they are substantially equal to each other, i.e., the relationship of fa≈fcc or fb≈fcc is satisfied, the frequency control circuit 11A recognizes that the relationship of fa≈fcc or fb≈fcc is satisfied and also sets the value of the frequency fcc at this point as the lower-limit frequency (the lower-limit value). The frequency control circuit 11A then ends this lower-limit detection processing routine.

Thus, the frequency control circuit 11A repeatedly executes the processing in step S12 to the processing in step S16 until the relationship of fa≈fcc or fb≈fcc is satisfied, which thereby allows for high-accuracy detection of the lower-limit frequency (the lower-limit value) of a frequency range in which the drive-current amplitude (the amplitude result signal 7a) exceeds a value defined by the drive-current threshold signal 8a1.

Although a case in which the frequency control circuit 11A controls the lower-limit frequency detection processing has been described by way of example in this embodiment, the present invention is not limited thereto. Similarly, the frequency control circuit 11A may control the upper-limit frequency detection processing in step S101 shown in FIG. 15. The frequency control circuit 11A in this embodiment controls processing for a method for detecting a frequency at which the amount of change in the phase-difference detection signal 6a is a maximum relative to the frequency, in the same manner as that in the first embodiment.

Thus, as in the first embodiment, the second embodiment can ensure that the driving frequency is set to a frequency in the vicinity of the resonant frequency while avoiding a range in which the phase difference between the drive voltage and the drive current cannot be accurately determined due to a small drive current. This arrangement, therefore, allows the ultrasonic actuator 2 to be driven with high driving efficiency.

Although the frequency control circuit 11A performs control so as to perform the upper-limit frequency detection processing (i.e., the processing in step S101 shown in FIG. 15) after performing the lower-limit frequency detection processing (i.e., the processing in step S100 shown in FIG. 5), the frequency control circuit 11A may perform control so as to perform the upper-limit frequency detection processing first and then perform the lower-limit frequency detection processing. Such an arrangement can provide the same advantages as the above-described embodiment.

Further, although the description in the second embodiment has been given of a case in which the entire actuator drive circuit 1A is constituted by circuits, the present invention is not limited thereto. For example, a microcomputer or the like can be used to constitute the ultrasonic-actuator drive circuit 1 with software. In such a case, a configuration in which the frequency control circuit 11A, the mode control circuit 10A, and so on are replaced with software may be employed.

### Third Embodiment

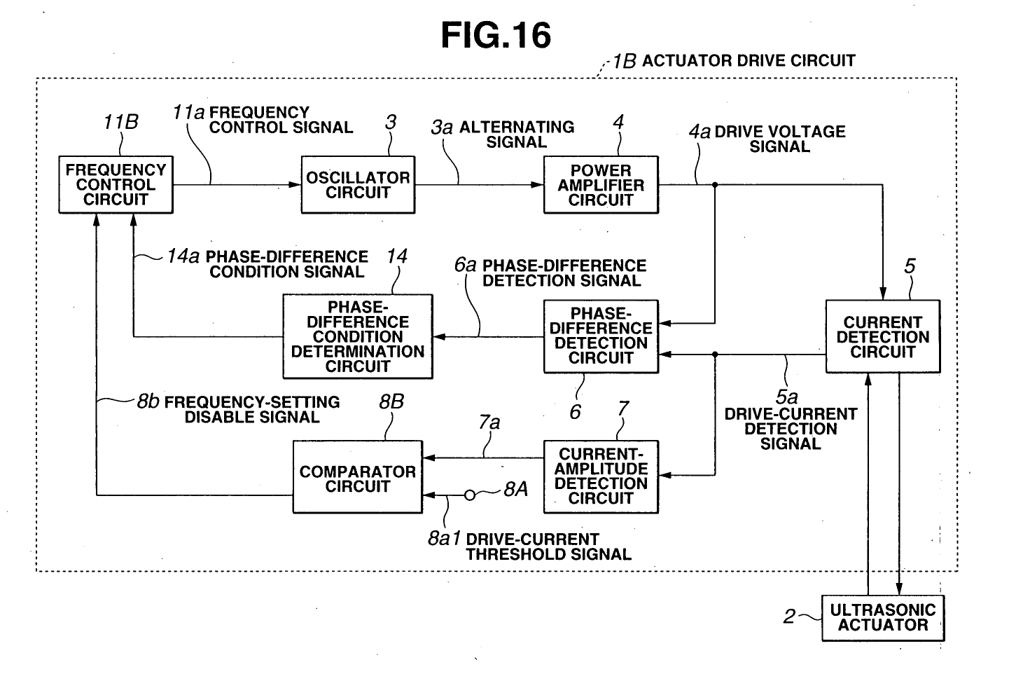

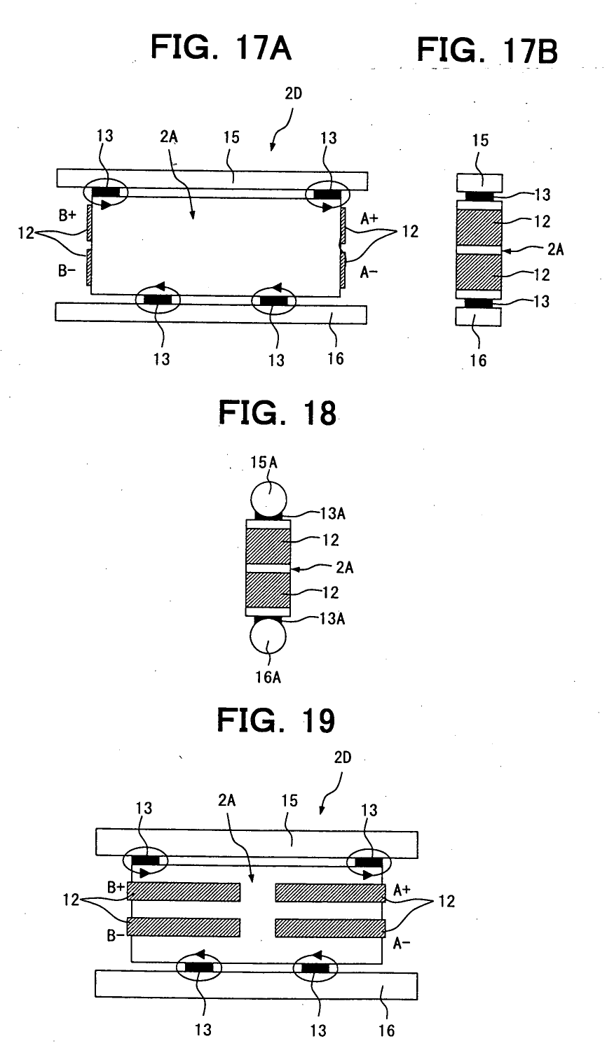

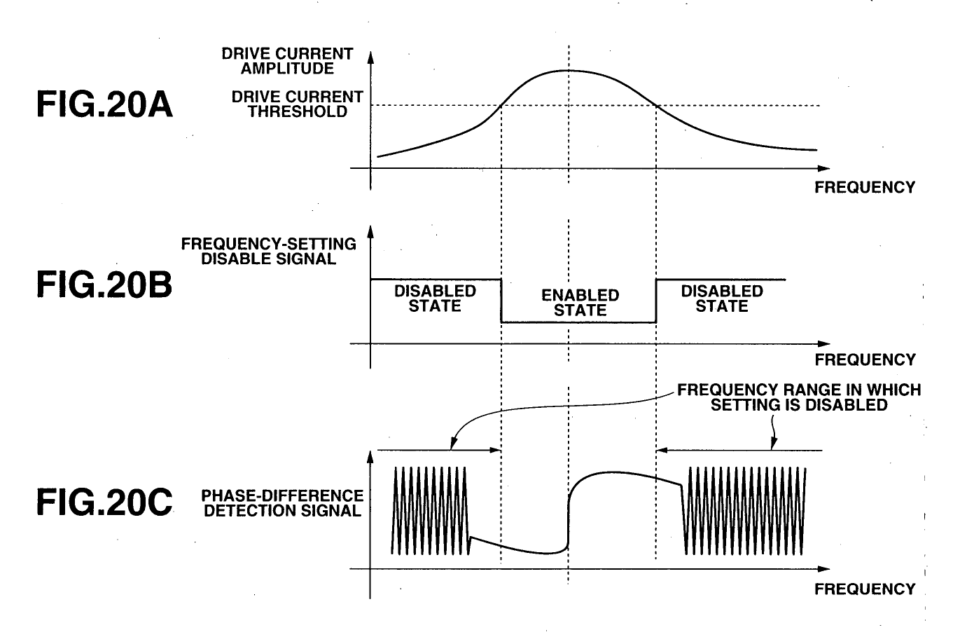

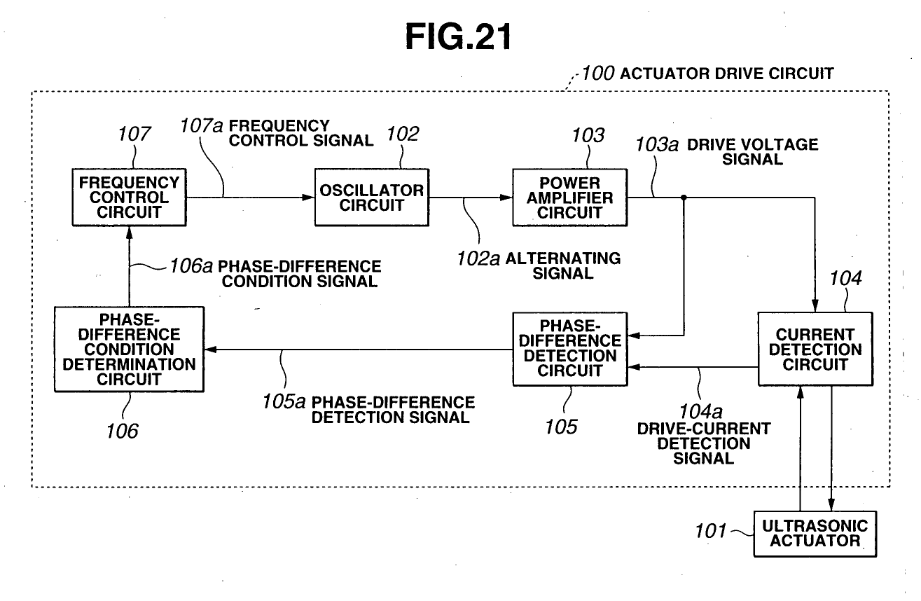

FIGS. 16 to 19 shows a third embodiment of the ultrasonic-actuator drive method of the present invention. Specifically, FIG. 16 is a block diagram showing the entire configuration of an ultrasonic-actuator drive device for realizing the ultrasonic-actuator drive method. FIGS. 17A and 17B show an example of the structure of an ultrasonic actuator used for the ultrasonic-actuator drive device according to the third embodiment, FIG. 17A being a front view and FIG. 17B being a side view. FIG. 18 is a side view showing a first modification of the ultrasonic actuator in this embodiment and FIG. 19 is a front view showing a second modification of the ultrasonic actuator in this embodiment. FIGS. 20A to 20C are graphs for describing an ultrasonic-actuator drive method of this embodiment. Specifically, FIG. 20A is a graph showing the characteristic of drive-current amplitude versus frequency, FIG. 20B is a graph showing the characteristic of frequency setting signal versus frequency, and FIG. 20C is a graph showing the characteristic of phase-difference detection signal versus frequency to describe a frequency range in which setting is disabled. In FIGS. 16 to 19, as in the first embodiment, the same elements are denoted with the same reference numerals, and thus the descriptions thereof are omitted and only different elements and portions will be described.

The ultrasonic-actuator drive device of this embodiment includes an ultrasonic-actuator drive circuit 1B and an ultrasonic actuator 2D. In the ultrasonic-actuator drive device of this embodiment, the structure of the ultrasonic actuator 2D is different from that in the first embodiment. Further, the ultrasonic-actuator drive circuit 1B is different from that in the first embodiment in that the frequency-range detection circuit 9 and the mode control circuit 10, which are included in the first embodiment, are eliminated and a phase-difference condition determination circuit 14 is additionally provided.

As shown in FIG. 16, the actuator drive circuit 1B is a circuit for driving the ultrasonic actuator 2D, and includes an oscillator circuit 3, a power-amplifier circuit 4, a current detection circuit 5, a phase-difference detection circuit 6, a current-amplitude detection circuit 7, comparator circuit 8B, and a frequency control circuit 11B, as well as the phase-difference condition determination circuit 14. The ultrasonic actuator 2D is connected to the power-amplifier circuit 4 via the current detection circuit 5.

The structure of the ultrasonic actuator 2D for use in this embodiment will now be described.

The ultrasonic-actuator drive device of this embodiment includes, for example, the ultrasonic actuator 2D shown in FIG. 17A. As shown in FIGS. 17A and 17B, this ultrasonic actuator 2D has an ultrasonic transducer 2A that includes a piezoelectric layered product, friction members 13, a first guide 15 and a second guide 16. The friction members 13 are provided at at least two spots of each of the top surface and the bottom surface of the piezoelectric layered product. The first guide 0.15 and the second guide 16 sandwich the piezoelectric layered product while applying a predetermined pressure thereto. Predetermined pressing means (not shown), including the guides 15 and 16, applies a predetermined pressure to the ultrasonic transducer 2A.

With this ultrasonic transducer 2A, similarly, when pressure applied to the ultrasonic transducer 2A varies, the displacement-to-frequency characteristic of the ultrasonic transducer 2A varies. That is, as shown in FIGS. 22A and 22B, as the pressure increases in the order of 0 kgf, 1 kgf, and 2 kgf, the overall displacement decreases and the displacement-to-frequency characteristic shifts toward higher frequencies. The displacement-frequency characteristics between a longitudinal primary vibration mode and a flexural secondary vibration mode are different from each other in the degree of the shifting toward higher frequencies. In this embodiment, the aspect ratio of the rectangular-prism piezoelectric layered product is set to a predetermined value so that the resonant frequency in the longitudinal primary vibration mode and the resonant frequency in the flexural secondary vibration mode match each other under a predetermined pressure.

It is desired that the friction members 13 are provided at positions where the ultrasonic actuator 2D can provide a highest-level output characteristic, i.e., where the ultrasonic transducer 2A can produce ultrasonic elliptical vibration at its highest level. As indicated by the arrows shown in FIG. 17A, elliptical vibration occurs at at least one of the friction members 13. In general, since elliptical vibration acts as a driving source, it is preferable to arrange the friction members 13 so that the sum total of driving forces resulting from vibrations produced at all the friction members 13 does not become “0”.

In this exemplary configuration, it is desirable that the ultrasonic transducer 2A has, for example, a longitudinal dimension of 5 to 20 mm. It is also desirable that pressure applied when the ultrasonic actuator 2D, including the ultrasonic transducer 2A and the ultrasonic guides 15 and 16, is constructed is, for example, 30 gf to 100 gf.

The characteristics of the ultrasonic actuator 2D and the stacking direction of the piezoelectric layered product of the ultrasonic transducer 2A in this exemplary structure are substantially the same as those in the first embodiment.

When the ultrasonic-actuator drive circuit 1B supplies a drive signal, which is an alternating signal, to the ultrasonic actuator 2D of this embodiment, elliptical vibration occurs in the vicinities of the friction members 13 of the ultrasonic transducer 2A to thereby drive the ultrasonic transducer 2A in the horizontal direction while being guided by the first and second guides 15 and 16.

Other operations are analogous to those in the first embodiment (see FIG. 2).

The exemplary structure described above can provide an ultrasonic actuator 2D that is preferably driven in an effective manner. The use of the ultrasonic transducer 2A having the above-described structure makes it possible to reduce component count and also to reduce variations in individual products. Further, when the device is designed such that the Q-value of the ultrasonic transducer 2A is constant, the resonant frequency in the longitudinal primary vibration mode and the resonant frequency in the flexural secondary vibration mode match each other under a predetermined pressure. This makes it possible to effectively execute the resonant-frequency detection processing routine described above.

In this embodiment, although the external electrodes 12 of the ultrasonic transducer 2A are arranged on two opposite side surfaces in the longitudinal direction of the piezoelectric layered product so as to define outer surfaces of the piezoelectric layered product, the present invention is not limited thereto. As in a second modification shown in FIG. 19, the external electrodes 12 may be extracted from side surfaces so as to be formed at surfaces of the piezoelectric layered product. Alternatively, the external electrodes 12 may be arranged at positions corresponding to reverse surfaces of the piezoelectric layered product.

In addition, as shown in FIG. 17A, the first and second guides 15 and 16 have been described as having a rectangular prism shape, the present invention is not limited thereto. For example, a cylindrical or a semi-cylindrical shape may be used as for a first guide 15A and a second guide 16A shown in a first modification shown in FIG. 18. In such a case, friction members 13A which have a U shape or V shape need to be used so as to correspond to the shapes of the first guide 15A and the second guide 16A.

The configuration of the ultrasonic-actuator drive circuit 1B of this embodiment will now be described.

As shown in FIG. 16, in the ultrasonic-actuator drive circuit 1B, the oscillator circuit 3 generates an alternating signal 3a having a frequency defined by a frequency control signal 11a output from the frequency control circuit 11B, and supplies the alternating signal 3a to the power-amplifier circuit 4.

The power-amplifier circuit 4 amplifies the alternating signal 3a and outputs and supplies an amplified drive voltage signal 4a to the ultrasonic actuator 2D via the current detection circuit 5. In accordance with the supplied drive voltage signal 4a, the ultrasonic actuator 2 is driven.

The current detection circuit 5 detects current flowing when the drive voltage signal 4a is supplied to the ultrasonic actuator 2D, and outputs and supplies a drive-current detection signal 5a, which indicates the result of the detection, to the phase-difference detection circuit 6 and the current-amplitude detection circuit 7.

The phase-difference detection circuit 6 detects a phase difference between the drive voltage signal 4a and the drive-current detection signal 5a and outputs and supplies a phase-difference detection signal 6a, which indicates the result of the detection, to the phase-difference condition determination circuit 14.

The phase-difference determination circuit 14 outputs a phase-difference condition signal 14a when the amount of change in the phase-difference detection signal 6a relative to the difference exceeds a predetermined value. The phase-difference condition determination circuit 14 has, for example, a differentiating circuit and a comparator circuit which are not shown, and supplies the phase-difference condition signal 14a generated by those circuits to the frequency control circuit 11B.

The current-amplitude detection circuit 7 detects the amplitude of the drive-current detection signal 5a and supplies an amplitude result signal 7a, which indicates the detected amplitude, to one input end of the comparator circuit 8A. A drive-current threshold signal 8a1, which serves as a reference for comparison processing, is supplied to the other input end of the comparator circuit 8A from drive-current threshold-signal generating means (not shown) connected to an input terminal 8A.

The comparator circuit 8A outputs and supplies a frequency-setting disable signal 8b to the frequency control circuit 11B, when the amplitude result signal 7a supplied from the current-amplitude detection circuit 7 falls below the drive-current threshold signal 8a1 having a predetermined value.

The frequency control circuit 11B serves as controlling means for controlling the entire ultrasonic-actuator drive circuit 1B of this embodiment. The frequency control circuit 11B sweeps the frequency and sets the driving frequency to a frequency at which the frequency-setting disable signal 8b is not output from the comparator circuit 8A and the phase-difference condition signal 14a is output from the phase-difference condition determination circuit 14.

The operation of the ultrasonic-actuator drive circuit 1B of this embodiment will now be described with reference to FIGS. 20A to 20C.

In the ultrasonic-actuator drive circuit 1B having the above-described configuration, the frequency control circuit 11B sweeps, for example, a frequency shown in FIG. 20A from high to low at a constant velocity. In response, the phase-difference detection signal 6a at this point varies in conjunction with the frequency sweep performed by the frequency control circuit 11B. Since the velocity of the frequency sweep is constant, causing the differentiating circuit (not shown), included in the phase-difference condition determination circuit 14, to differentiate the phase-difference detection signal 6a can obtain the amount of change in the phase-difference detection signal 6a relative to the frequency.

Thus, the phase-difference condition determination circuit 14 compares outputs from the differentiating circuit (not shown) using the comparator circuit (not shown), which makes it possible to determine whether or not the amount of change in the phase-difference detection signal 6a relative to the frequency exceeds a predetermined value (see FIG. 20C). The determination result, i.e., an output of the comparator circuit (not shown), is supplied to the frequency control circuit 11B as the phase-difference condition signal 14a. In response to the phase-difference condition signal 14a, in an enabled period in which the frequency-setting disable signal 8b shown in FIG. 20B is at a low level, the frequency control circuit 11B recognizes the phase-difference condition signal 14a, stops the sweeping, and detects a frequency in the vicinity of the resonant frequency. The frequency control circuit 11B then sets the driving frequency to the detected frequency, in the same manner as in the first embodiment.

In this embodiment, the frequency control circuit 11B recognizes the frequency setting disable signal 8b output from the comparator circuit 8A, in a frequency range from which the phase cannot be detected due to a small drive current, as shown in FIG. 20C. This allows the frequency control circuit 11B to perform control so that the drive frequency is not set to a frequency that is irrelevant to the resonant frequency.

Thus, according to this embodiment, the above-described operation can ensure that the driving frequency is set to a frequency in the vicinity of the resonant frequency while avoiding a range in which the phase difference between the drive voltage and the drive current cannot be accurately determined due to a small drive current. This arrangement, therefore, allows the ultrasonic actuator 2D to be driven with high driving efficiency.

Although the description in this embodiment has been given of a case in which the phase-difference condition determination circuit 14 includes the differentiating circuit and the comparator circuit, the present invention is not limited thereto. The phase-difference condition determination circuit 14 may be realized with software that scans frequencies in a discrete manner, stores a phase-difference detection signal relative to the frequency, and compares the amount of change in the phase-difference detection signal relative to the frequency.

The configuration of any of the ultrasonic actuators in the first to third embodiments may be used for the ultrasonic-actuator drive device according to the present invention, and the configurations of the ultrasonic actuators may be used in combination as needed.

In this invention, it is apparent that various modification different in a wide range can be made on this basis of this invention without departing from the spirit and scope of the invention. This invention is not restricted by any specific embodiment, including the first to third embodiments described above, except being limited by the appended claims.

1. A method for driving an ultrasonic actuator by supplying an alternating signal to an ultrasonic transducer in which piezoelectric plates and internal electrodes are alternately stacked, the method comprising:
detecting a frequency at which a phase difference between a voltage and current of the alternating signal is in a predetermined state, from a frequency range in which an amplitude ratio between the voltage and the current of the alternating signal is more than or equal to a predetermined value; and
setting a driving frequency to the detected frequency.

2. The method for driving an ultrasonic actuator according to claim 1, further comprising: a first step of detecting, as a lower-limit frequency, a minimum frequency at which the amplitude ratio between the voltage and the current of the alternating signal is more than or equal to the predetermined value, and detecting, as an upper-limit frequency, a maximum frequency at which the amplitude ratio between the voltage and the current of the alternating signal is more than or equal to the predetermined value; and
a second step of detecting a frequency at which the phase difference between the voltage and the current of the alternating signal is in a predetermined state, from a frequency range defined by the upper-limit frequency and the lower-limit frequency which are detected in the first step; and
a third step of setting the driving frequency to the frequency detected in the second step.

3. The method for driving an ultrasonic actuator according to claim 2, wherein the lower-limit frequency is detected while the frequency of the alternating signal is swept from low to high and the upper-limit frequency is detected while the frequency of the alternating signal is swept from high to low.

4. The method for driving an ultrasonic actuator according to claim 2, wherein the lower-limit frequency is detected while the frequency of the alternating signal is changed in a discrete manner and the upper-limit frequency is detected while the frequency of the alternating signal is changed in a discrete manner.

5. The method for driving an ultrasonic actuator according to claim 1, wherein a determination as to whether or not the amplitude ratio between the voltage and the current of the alternating signal is more than or equal to the predetermined value and a determination as to whether or not the phase difference between the voltage and the current of the alternating signal is in the predetermined state are performed at the same time, a frequency at which the amplitude ratio is more than or equal to the predetermined value and the phase difference is in the predetermined state is detected, and the driving frequency is set to the detected frequency.

6. The method for driving an ultrasonic actuator according to claim 1, wherein the predetermined state is a state in which an amount of change in the phase difference relative to a frequency is a maximum.

7. The method for driving an ultrasonic actuator according to claim 1, wherein the predetermined state is a state in which an amount of change in the phase difference relative to a frequency exceeds a predetermined value.

8. The method for driving an ultrasonic actuator according to claim 1, wherein the ultrasonic transducer comprises: a piezoelectric layered product in which piezoelectric plates are stacked in the same direction; friction members provided at side surfaces of the piezoelectric layered product so as to be in contact with a driven portion with a predetermined pressure; internal electrodes provided in the piezoelectric layered product, the internal electrodes having a first electrode group and a second electrode group; and a first external electrode group and a second external electrode group which are electrically connected to the internal electrodes, and wherein a driving portion supplies the alternating signal to the first external electrode group and/or the second external electrode group to simultaneously produce a first vibration mode and a second vibration mode, thereby producing ultrasonic elliptical vibration at the ultrasonic transducer.

9. The method for driving an ultrasonic actuator according to claim 1, wherein the ultrasonic transducer is sandwiched by a first guide and a second guide, which apply a predetermined pressure to the piezoelectric layered product, with the friction members interposed therebetween.

10. The method for driving an ultrasonic actuator according to claim 8, wherein the piezoelectric layered product has a predetermined outside dimension so that a resonant frequency in a first vibration mode and a resonant frequency in a second vibration mode match each other under the predetermined pressure.

11. The method for driving an ultrasonic actuator according to claim 9, wherein the piezoelectric layered product has a predetermined outside dimension so that a resonant frequency in the first vibration mode and a resonant frequency in the second vibration mode match each other under the predetermined pressure.

12. A device for driving an ultrasonic actuator by supplying an alternating signal to an ultrasonic transducer in which piezoelectric plates and internal electrodes are alternately stacked, the device comprising:
a drive circuit for generating the alternating signal;
an amplitude detection circuit for detecting an amplitude ratio between a voltage and current of the alternating signal;
a phase-difference detection circuit for detecting a phase difference between the voltage and the current of the alternating signal; and
a control circuit for setting a frequency of the alternating signal in accordance with the amplitude ratio and the phase difference,
wherein the control circuit detects a frequency at which the phase difference is in a predetermined state from a frequency range in which the amplitude ratio is more than or equal to a predetermined value, and sets a driving frequency to the detected frequency.

13. The device for driving an ultrasonic actuator according to claim 12, wherein the ultrasonic transducer comprises: a piezoelectric layered product in which piezoelectric plates are stacked in the same direction; friction members provided at side surfaces of the piezoelectric layered product so as to be in contact with a driven portion with a predetermined pressure; internal electrodes provided in the piezoelectric layered product, the internal electrodes having a first electrode group and a second electrode group; and a first external electrode group and a second external electrode group which are electrically connected to the internal electrodes,
wherein a driving portion supplies the alternating signal to the first external electrode group and/or the second external electrode group to simultaneously produce a first vibration mode and a second vibration mode, thereby producing ultrasonic elliptical vibration at the ultrasonic transducer.

14. The device for driving an ultrasonic actuator according to claim 12, wherein the ultrasonic transducer is sandwiched by a first guide member and a second guide member, which apply a predetermined pressure to the piezoelectric layered product, with the friction members interposed therebetween.

15. The device for driving an ultrasonic actuator according to claim 13, wherein the piezoelectric layered product has a predetermined outside dimension so that a resonant frequency in the first vibration mode and a resonant frequency in the second vibration mode match each other under the predetermined pressure.

16. The device for driving an ultrasonic actuator according to claim 14, wherein the piezoelectric layered product has a predetermined outside dimension so that a resonant frequency in a first vibration mode and a resonant frequency in a second vibration mode match each other under the predetermined pressure.
